(19) United States
(12) Patent Application Publication
(10) Pub. No.: US 2012/0098088 A1
(43) Pub. Date: Apr. 26, 2012

(54) METHOD OF FORMING ISOLATION STRUCTURE AND SEMICONDUCTOR DEVICE WITH THE ISOLATION STRUCTURE

(75) Inventors: Jyun Huan CHEN, Taipei City (TW); Yi Jung CHEN, Sanchong City (TW)

(73) Assignee: NANYA TECHNOLOGY CORP., Kueishan (TW)

(21) Appl. No.: 12/909,207

(22) Filed: Oct. 21, 2010

(51) Int. Cl. H01L 29/06; H01L 21/762

(52) U.S. Cl. 257/510; 438/429; 257/E29.02; 257/E21.546

(57) ABSTRACT

A semiconductor device includes a substrate and an isolation structure, which includes a trench in the substrate, a lower filling layer at the bottom of the trench, and an upper filling layer on the lower filling layer, wherein the lower filling layer is denser than the upper filling layer, and the lower filling layer contains chlorine. The method for forming an isolation structure includes the steps of forming a trench in a substrate wherein the trench comprises side surfaces and a bottom surface, forming a nitride liner on the side surfaces of the trench, growing an epitaxial silicon layer from to the bottom surface of the trench, oxidizing the epitaxial silicon layer to form a lower filling layer in the lower portion of the trench, and filling a portion of the trench above the lower filling layer with dielectric material.

### DESCRIPTION

1. Technical Field

The present invention relates to a trench isolation structure and method of forming the same. More particularly, the present invention relates to a shallow trench isolation structure and a method of forming the same with epitaxy and oxidation processes.

2. Background

Conventional integrated circuit fabrication processes use a local oxidation of silicon (LOCOS) technique or shallow trench isolation (STI) technique to electrically isolate electronic devices from each other, so as to avoid short circuits and cross interference. Due to the LOCOS technique's forming a field oxide layer covering a larger wafer area and also because it forms a “bird's beak” pattern, advanced integrated circuit fabrication generally selects the STI technique to electrically isolate electronic devices on the wafer.

STI (shallow trench isolation) is generally applied on CMOS process technology nodes of 250 nanometers and smaller. STI can be typically filled with oxide by chemical vapor deposition, for example, high density plasma chemical vapor deposition (HDP-CVD) using silane as a precursor. With the width of the STI trenches getting smaller and the trench aspect ratios increasing, problems such as pinch-off near the top of the trench or the creation of voids or seams become challenges to the use of CVD.

The STI can be filled by spin-on deposition. A substrate is spun to uniformly spread liquid dielectric material thereon to fill the STI, and the coating is then baked to solidify. The spin-on deposition can fill the trenches without causing pinch-off, void or seam problems, and thus becomes a solution for the deposition of dielectric materials. The spin-on dielectric materials need densification processes, such as electron-beam and steam oxidation processes, to achieve acceptable bulk density. However, trenches with narrow openings limit dielectric material flow during the curing process. As a result, the bottom portion of the densified dielectric material is not as dense as the upper portion of the densified dielectric material, likely failing to provide required electrical isolation.

In view of the above discussions, the present trench filling methods to have many problems. Thus, a new trench filling method is needed.

### SUMMARY

To solve the problems of the above-mentioned prior art, one aspect of the present invention discloses a semiconductor device, which comprises a substrate and an isolation structure. The isolation structure includes a trench in the substrate, a lower filling layer at the bottom of the trench, and an upper filling layer on the lower filling layer, wherein the lower filling layer is denser than the upper filling layer.

To solve the problems of the above-mentioned prior art, another aspect of the present invention discloses a semiconductor device, which comprises a substrate and an isolation trench. The isolation structure comprises a trench in the substrate, a lower filling layer at the bottom of the trench, an upper filling layer on the lower filling layer, wherein the lower filling layer is formed of silicon oxide containing chlorine, and the upper filling layer is formed of silicon oxide substantially without chlorine.

To solve the problems of the above-mentioned prior art, another aspect of the present invention discloses a method of forming an isolation structure, comprising the steps of forming a trench having side surfaces and a bottom surface in a substrate, forming a nitride liner on the side surfaces of the trench, growing an epitaxial silicon layer from the bottom surface of the trench, oxidizing the epitaxial silicon layer to form a lower filling layer in the lower portion of the trench, and filling a portion of the trench above the lower filling layer with dielectric material.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may to be readily utilized as a basis for modifying or designing other structures or processes for carrying out the same purposes as those of the present invention. It should also be realized by those skilled in the art that such equivalent constructions do not depart from the spirit and scope of the invention as set forth in the appended claims.

### BRIEF DESCRIPTION OF THE DRAWINGS

The accompanying drawings, which are incorporated in and constitute a part of this specification, illustrate embodiments of the disclosure and, together with the description, serve to explain the principles of the invention.

FIGS. 1 to 6 are cross-sectional views showing a method of forming an isolation structure according to one embodiment of the present invention; and

FIG. 7 is a cross-sectional view showing an isolation structure according to one embodiment of the present invention.

### DETAILED DESCRIPTION

In one embodiment of the present invention, dielectric material is initially formed in the lower portion of a trench to reduce the filling depth of the trench so that conventional deposition methods can be applied to the trench filling. In one embodiment of the present invention, the lower portion of the trench can be filled with dielectric material or material that can be oxidized to become dielectric material. The upper portion of the trench, above the filled dielectric material, can then be filled with, for example, spin-on dielectric or filled by a chemical vapor deposition (CVD) process.

In an illustrated embodiment, the lower portion of the trench can be filled with epitaxial silicon, which is subsequently converted into silicon oxide by thermal oxidation process. In this instance, a nitride liner can be deposited on the side surfaces of the trench such that epitaxial silicon can be selectively formed on the silicon bottom surface of the trench rather than on the side surfaces of the trench. The epitaxial silicon employed to fill the lower portion the trench can be formed from sources including chlorine. Thus, traces of chlorine may be left in the lower filling layer.

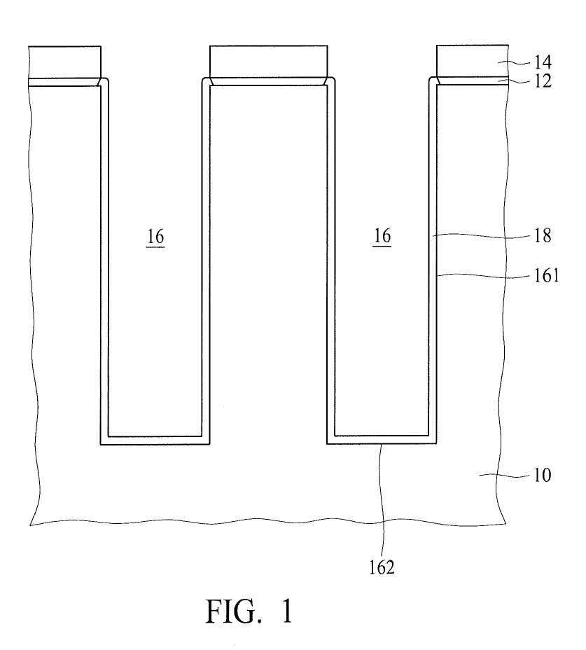

FIGS. 1 to 6 are cross-sectional views showing a method of forming an isolation structure according to one embodiment of the present invention. As shown in FIG. 1, a thin oxide 12 is thermally grown on the substrate 10 with a thickness, for example, in a range of from 30 to 100 angstroms. A hard mask layer 14 is subsequently formed on the thin oxide 12 with a thickness, for example, in a range of 200 to 1500 angstroms. The hard mask layer 14 can be a layer of silicon nitride, which can be formed by chemical vapor deposition. The hard mask 14 is able to be used as a stop for the chemical mechanical polishing (CMP) process.

A photoresist mask (not shown) can be provided to etch out the trenches 16. The photoresist mask is formed by using a conventional photolithographic process. After the trenches 16 are formed in the substrate 10, the photoresist mask can be removed by a conventional resist strip process.

As shown in FIG. 1, after the photoresist mask is stripped, an oxide layer 18 is thermally grown on the side surfaces 161 and the bottom surfaces 162 of the trenches 16. The oxide layer 18 can cause the rounding of the upper corners of the trenches 16, and can also repair the damage of the side surfaces 161 if the trenches 16 are etched by reactive ion etching.

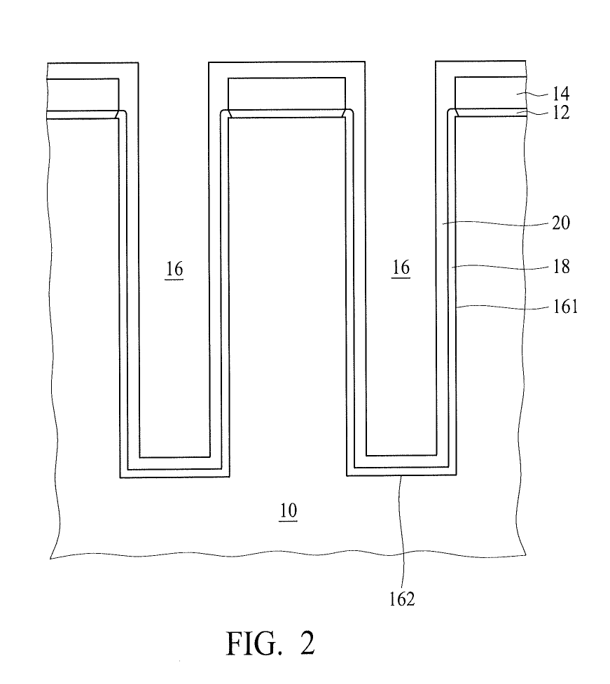

Referring to FIG. 2, a nitride liner 20 is formed on the oxide layer 18 functioning to relieve stress between the nitride liner 20 and the substrate 10. The nitride liner 20 can be formed by deposition technique such as CVD, and can have a thickness of from 5 angstroms to 10 angstroms.

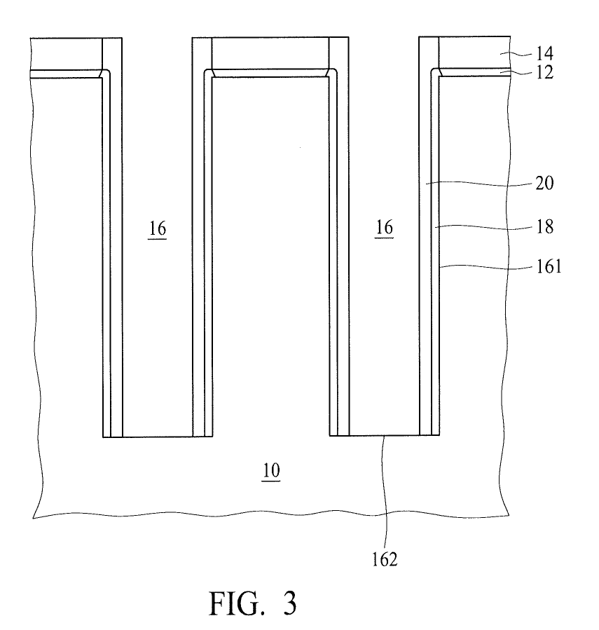

As shown in FIGS. 2 and 3, an etch process is applied to selectively etch away the nitride liner 20 and the oxide layer 18 from the bottom surfaces 162 of the trenches 16 so as to expose the bottom surfaces 162 of the trenches 16. In one embodiment, the etch process is a dry etch process.

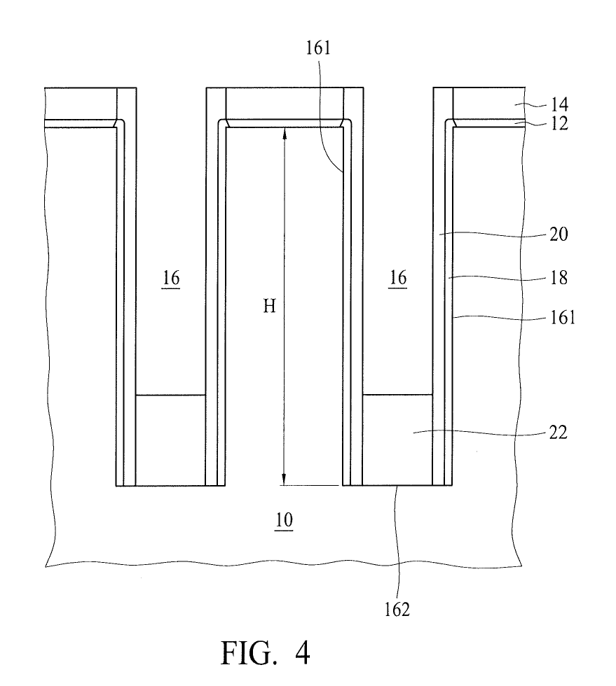

Referring to FIG. 4, epitaxial deposition of silicon is carried out to grow an epitaxial silicon layer 22 on the bottom surface 162 of each trench 16. Epitaxial silicon growth will be selectively applied to areas of exposed silicon. In each trench 16, the nitride liner 20 is formed in a manner that covers the side surfaces 161 of the trench 16 while exposing the bottom surface 162 of the trench 16; thus, epitaxial silicon selectively grows on the bottom surface 162 rather than on the side surfaces 161. Because the nitride liner 20 can prevent epitaxial silicon growth, the epitaxial silicon will not be formed on the side surfaces 161 of the trench 16 so as to prevent the trench 16 from pinching off during the epitaxial deposition process.

Specifically, the epitaxial silicon can be grown using vapor-phase epitaxy. The epitaxial silicon can be formed from a material such as dichlorosilane, trichlorosilane, or silicon tetrachloride. Because these sources include chlorine, traces of chlorine may be left in the epitaxial silicon layer 22 after it is formed.

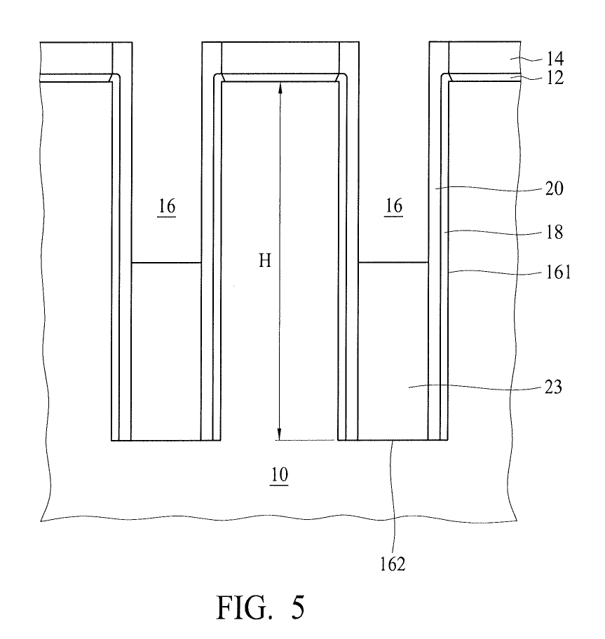

After the epitaxial silicon layer 22 is formed, the epitaxial silicon layer 22 is subjected to thermal oxidation to transform it into a lower filling layer 23 of silicon oxide as shown in FIG. 5. Preferably, steam oxidation at a temperature of approximately 800 to 1000 degrees Celsius is employed for such transformation. In one embodiment, the substrate 10 is placed in a curing chamber heated by steam to a temperature of 800 to 1000 degrees Celsius. Compared to an oxide layer formed using a low-temperature deposition process, the lower filling layer 23 can have higher density and a low content of carbon or hydrogen impurity.

After the thermal oxidation process is finished, the lower portion of the trench 16 is filled with the lower filling layer 23. As such, the depth of the filling space of the trench 16 is reduced; thus, conventional trench-filling techniques can be employed. The height of the lower filling layer 23 depends on the embodiments employed. In one embodiment, the lower filling layer 23 expands to an extent such that the aspect ratio of the remaining portion of the trench 16, above the lower filling layer 23, is less than 12. In another embodiment, the lower filling layer 23 can expand to a height of about one-third of the original depth H of the trench 16. In another embodiment, the lower filling layer 23 can be formed in such a manner that the remaining portion of the trench 16 can be filled by conventional deposition methods without causing the problems that are created when the conventional deposition methods are directly applied to fill the trench 16. Correspondingly, to achieve the desired height of the lower filling layer 23, the epitaxial silicon layer 22, in one embodiment, is grown to a height of one-seventh to one-sixth of the depth H of the trench 16.

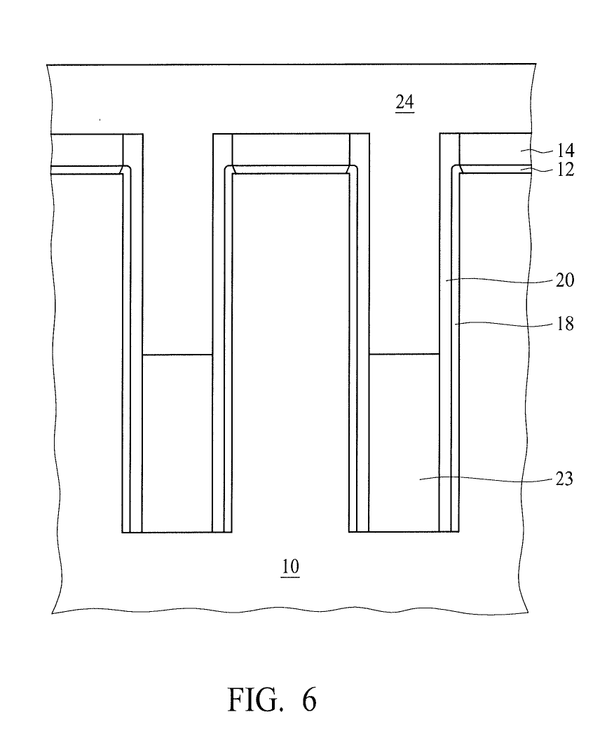

As shown in FIG. 6, after the lower filling layer 23 is formed, a dielectric material 24, such as silicon oxide, is deposited to fill the remaining portion of the trench 16. The dielectric material 24 can be deposited using a chemical vapor deposition process such as high density plasma chemical vapor deposition. The dielectric material 24 can alternatively be liquid material and deposited using a spin-on deposition process, and subsequently solidified and densified to achieve acceptable bulk density. In addition to the aforementioned deposition processes, other processes for filling trenches are applicable.

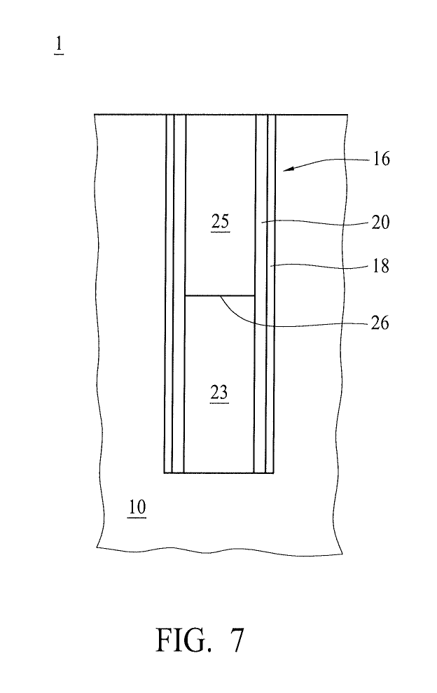

After the trenches 16 are fully filled, the chemical-mechanical polishing process or other etch-back process can be used to remove undesired dielectric materials 24 on the top of the substrate 10. Thereafter, the hard mask layer 14 is selectively removed, and the thin oxide 12 is subsequently removed. Consequently, an isolation structure 1 with an upper filling layer 25 filling the upper portion of the trench 16, as shown in FIG. 7, is completed. Conventional processes may then follow to form a semiconductor device such as a memory, microcontroller, analog circuitry, etc.

Referring to FIG. 7, the trench 16 is filled by two different processes to form the isolation structure 1. The bottom of the trench is filled with a lower filling layer 23 formed by oxidizing epitaxial silicon produced from a source selected from the group consisting of dichlorosilane, trichlorosilane, is and silicon tetrachloride, and the upper filling layer 25 on the lower filling layer 23 is filled by a chemical vapor deposition process or spin-on deposition process. In consequence, the lower filling layer 23 is denser than the upper filling layer 25, and the layers are separated by an interface 26. The spin-on deposition uses liquid materials dripped on the substrate 10. The substrate 10 is spun to spread the liquid materials uniformly over the surface of the substrate 10, filling the low points on the substrate 10. An example of the spin-on dielectric material is AZ Spinfil™ available from AZ Electronic Material or Dow Corning Spin-on STI available Dow Coring, Inc., of Midland, Mich. However, a skilled practitioner will appreciate that many dielectric materials can be used for the purpose. The lower filling layer 23 is formed from a chlorine-containing source, and therefore may contain chlorine. The upper filling layer 25 can be formed from a mixture of silane and oxygen, a mixture of silane and nitrous oxide (N₂O), a mixture of silane and carbon dioxide, tetraethylorthosilicate (TEOS), or a spin-on dielectric. In these instances, the upper filling layer 25 may contain carbon, hydrogen, or nitrogen rather than chlorine.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the to specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein, may be utilized according to the present invention. Accordingly, the appended claims are intended to include within their scope such processes, machines, manufacture, compositions of matter, means, methods, or steps.

What is claimed is:

1. A semiconductor device, comprising:
a substrate; and
an isolation structure comprising a trench in the substrate, a lower filling layer at the bottom of the trench, and an upper filling layer on the lower filling layer, wherein the lower filling layer is denser than the upper filling layer.

2. The semiconductor device of claim 1, wherein the upper filling layer comprises spin-on dielectric material.

3. The semiconductor device of claim 1, wherein the height of the lower filling layer is about one-third of the depth of the trench.

4. The semiconductor device of claim 1, wherein the isolation structure further comprises a nitride liner on side surfaces of the trench.

5. A semiconductor device, comprising:
a substrate; and
an isolation structure comprising a trench in the substrate, a lower filling layer at the bottom of the trench, and an upper filling layer on the lower filling layer, the lower filling layer is formed of silicon oxide containing chlorine, and the upper filling layer is formed of silicon oxide substantially without chlorine.

6. The semiconductor device of claim 5, wherein the upper filling layer comprises spin-on dielectric material.

7. The semiconductor device of claim 5, wherein the height of the lower filling layer is about one-third of the depth of the trench.

8. The semiconductor device of claim 5, wherein the isolation structure comprises a nitride liner on side surfaces of the trench.

9. A method of forming an isolation structure, comprising the steps of:
forming a trench in a substrate, wherein the trench comprises side surfaces and a bottom surface;
forming a nitride liner on the side surfaces of the trench;
growing an epitaxial silicon layer from the bottom surface of the trench;
oxidizing the epitaxial silicon layer to form a lower filling layer in the lower portion of the trench; and
filling a portion of the trench above the lower filling layer with dielectric material.

10. The method of claim 9, wherein the step of oxidizing the epitaxial silicon layer is performed in a steam ambient environment.

11. The method of claim 10, wherein the epitaxial silicon layer is oxidized at a temperature of approximately 800 to 1000 degrees Celsius.

12. The method of claim 9, wherein the portion of the trench above the filling layer is filled using a spin-on deposition process.

13. The method of claim 9, wherein the portion of the trench above the lower filling layer is filled using a chemical vapor deposition process.

14. The method of claim 9, wherein the step of forming a nitride liner on the side surfaces of the trench further comprises the steps of:
depositing an oxide layer;
depositing the nitride liner on the oxide layer; and
removing the oxide layer and the nitride liner on the bottom surface of the trench.

15. The method of claim 9, wherein the height of the lower filling layer is about one-third of the depth of the trench.

16. The method of claim 9, wherein the epitaxial silicon layer is grown to a height of one-seventh to one-sixth of the depth of the trench.

17. The method of claim 9, wherein the dielectric material comprises silicon oxide.

18. The method of claim 9, wherein the epitaxial silicon layer is formed from a material selected from the group consisting of dichlorosilane, trichlorosilane, and silicon tetrachloride.
